(19) United States
(12) Patent Application Publication
(10) Pub. No.: US 2006/0197135 A1
(43) Pub. Date: Sep. 7, 2006

(54) Semiconductor device having a cylindrical capacitor element

(75) Inventor: Yasukazu Inoue, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC

(21) Appl. No.: 11/365,855

(22) Filed: Mar. 2, 2006

(30) Foreign Application Priority Data
Mar. 4, 2005 (JP) 2005-060055

(51) Int. Cl. H01L 29/00; H01L 27/108; H01L 21/8242; H01L 21/00

(52) U.S. Cl. 257/306; 438/253; 438/396; 257/532

(57) ABSTRACT

A semiconductor device includes a cylindrical capacitor having a bottom electrode, a capacitor insulator film and a top electrode. The top electrode includes first and second electrode portions insulated from each other and opposing the inner surface and outer surface, respectively, of the bottom electrode. The second electrode portion is deposited prior to the bottom electrode, preventing collapse of the bottom electrode during manufacture of the semiconductor device.

### BACKGROUND OF THE INVENTION

1. Field of the Invention

The present invention relates to a semiconductor device having a cylindrical capacitor and a method of manufacturing the same. More particularly, it relates to a technique for manufacturing a semiconductor device having a cylindrical capacitor element generally called Crown-type capacitor element.

2. Description of the Related Art

Recently, to increase the scale and performance of a semiconductor device such as a DRAM device, reduction in the size of constituent elements in the semiconductor device is advanced. For this reason, the area allowed for the capacitor element configuring the main constituent element of the DRAM device is indispensably reduced. Thus, a capacitor element having a larger capacitance with a smaller occupied is desired. FIG. 3 shows an example of a conventional semiconductor device having the capacitor element.

The semiconductor device 50 is configured as a DRAM device having a cylindrical capacitor element. The semiconductor device 50 has MIS-type transistors formed on the main surface of a silicon substrate 11, and capacitor elements connected to the transistors and formed to overlie the transistors. The capacitor elements each have a substantially cylindrical bottom electrode 55 formed in the interior of a cylindrical opening 53 penetrating through a thick insulating film 51, a capacitor insulator film 56 formed on the inner side surface and the upper surface of the bottom electrode 55, and a top electrode 57 arranged opposite to the bottom electrode 55 with an intervention of the capacitor insulator film 56. The semiconductor device 50 has a CUB (Capacitor Under Bit Line) structure in which the capacitor element is arranged below a bit line 39.

FIGS. 4A to 4C consecutively show respective steps in a process for manufacturing the semiconductor device 50 shown in FIG. 3.

After the MIS-type transistors are formed on the main surface of the silicon substrate 11, the thick insulating film 51 is deposited to overlie the MIS-type transistors. Then, openings 53 reaching the top of contact plugs 22c are formed to penetrate the insulating film 51. The contact plugs 22c are connected to the respective drains 13c of the transistors. Subsequently, after a polysilicon film 54 is deposited on the entire surface (FIG. 4A), anisotropic etching is performed, and the bottom electrodes 55 made of a polysilicon is formed on the inner side surface of the openings 53.

Then, the capacitor insulator film 56 and the top electrodes 57 are consecutively formed, covering the bottom electrodes 55 (FIG. 4B). Subsequently, plugs 38 connected to the contact plugs 22a and the bit lines 39 connected to the plugs 38 are formed (FIG. 4C). The contact plugs 22a are connected to the sources 13a of the transistors. Further, formation of the insulating film and interconnection pattern is performed. Thus, the semiconductor device 50 can be obtained as a DRAM device.

The semiconductor device 50 is designed to have a larger depth of the cylindrical openings 53. Thereby, the surface area of the bottom electrodes is increased without increasing the area occupied by the capacitor elements, and the capacitance of the capacitor elements can be increased. However, in the semiconductor device of next generation, it is required for the capacitor elements to have a larger capacitance with a smaller occupied area to realize a further increase in the scale and performance of the semiconductor device. As an example of such a cylindrical capacitor element, a so-called Crown-type capacitor element is studied. FIG. 5 shows the configuration of the semiconductor device having a Crown-type capacitor element.

In manufacture of the semiconductor device 60 shown in FIG. 5, the insulating film such as 51 in the semiconductor device 50 shown in FIG. 3B on the outer side of the cylindrical portion of the bottom electrode such as 55 in FIGS. 3B is removed subsequent to the formation of the bottom electrode. Thus, the structure of a part of the capacitor element including another top electrode 57 is formed to oppose the outer side surface of the bottom electrode 55 to thereby increase the capacitance of the capacitor element.

In comparison of the capacitor structure shown in FIG. 5 with the capacitor element of the equivalent size shown in FIG. 3, twice as much capacitance as that of the semiconductor device 50 shown in FIG. 3 can be obtained in the capacitor element shown in FIG. 5 due to Utilizing of the outer side surface of the bottom electrode 55 within the capacitor structure. The semiconductor device 60 having the Crown-type capacitor element is described, for example, in JP-A-2004-040059 (FIG. 4 in the publication).

It is to be noted that, in the Crown-type capacitor element shown in FIG. 5, right after the insulating film formed on the outside of the cylindrical bottom electrode 55 is removed, the capacitor element stands on the underlying structure without an external or internal support. This requires a larger mechanical strength for the bottom electrode 55, and there arises a problem that inclination or collapse of the bottom electrode 55 may occurs. Particularly, in a washing step of a wafer subsequent to the formation of the bottom electrode 55, there occurs the problem that the bottom electrode 55 inclines or collapses toward droplets in contact with the bottom electrode, due to s the surface tension of the droplets. For solving this problem, JP-A-2004-040059 (FIG. 4) describes a semiconductor manufacturing method wherein a base for supporting the bottom electrode is formed on the outside of the bottom electrode.

In the semiconductor device described in JP-A-2004-040059, the bottom electrode projecting on the insulating film is externally supported by the base for reinforcement. Accordingly, as compared with the conventional manufacturing method as described before, inclination or collapse of the bottom electrode can be suppressed.

However, to assure the sufficient surface area of the bottom electrode, it is necessary to largely limit the height of the base. Hence, inclination or collapse of the part of the bottom electrode projecting above the base cannot be suppressed with a satisfactory level.

### SUMMARY OF THE INVENTION

In view of the above problems in the conventional techniques, it is an object of the present invention to provide a semiconductor device having a cylindrical capacitor such as a Crown-type capacitor element which is capable of preventing the occurrence of inclination or collapse of the bottom electrode during the process for manufacture of the semiconductor device.

The present invention also relates to a method for manufacturing the semiconductor device as described above.

The present invention provides a semiconductor device including: a semiconductor substrate; and a cylindrical capacitor overlying the semiconductor substrate and including a bottom electrode,first and second capacitor insulator films and a top electrode, the top electrode including a first electrode portion opposing an outer surface of the bottom electrode with an intervention of the first capacitor insulator film and a second electrode portion insulated from the first electrode portion and opposing an inner surface of the bottom electrode with an intervention of the second capacitor insulator film.

The present invention also provides a method for manufacturing a semiconductor device including: forming a first insulator film overlying a semiconductor substrate; forming a contact plug penetrating the first insulator film to reach a portion of the semiconductor substrate; forming a first conductive film on the insulator film and a top surface of the contact plug; forming a cylindrical opening in the first conductive film to expose the top surface of the contact plug; forming a first capacitor insulator film on a sidewall of the cylindrical opening; forming a second conductive film on the first capacitor insulator film and the top surface of the contact plug, to configure a bottom electrode connected to the contact plug; forming a second capacitor insulator film on the bottom electrode and the contact plug; forming a third conductive film on the second capacitor insulator film; and connecting the first and third conductive films to at least one source line having a specific potential, thereby configuring the first and second conductive films as first and second top electrodes;

According to the semiconductor device of the present invention, the second top electrode is insulated from the first top electrode. Thus, the first top electrode and the second top electrode can be connected to different power supplies. In this case, a power supply noise generated at the first top electrode or the second top electrode can be reduced by operating the other top electrode as a buffer, and the malfunction of the capacitor element due to the power supply noise can be suppressed.

It is preferable in the semiconductor device of the present invention that the second top electrode be connected to the potential of ½ of the power supply potential. In this case, the first top electrode may be connected to the potential lower Man ½ of the power supply potential. Thereby, a potential difference larger than the potential difference in the conventional Crown-type can be obtained between the bottom electrode and the first top electrode, and the capacitance of the capacitor element can be increased. More preferably, the power supply noise generated at the first top electrode and the power supply noise generated at the second top electrode cancel each other if the first top electrode is connected to the ground potential. Consequently, the power supply noise generated on the top electrode can be effectively reduced.

In accordance with the method for manufacturing the semiconductor device of the present invention, the side surface of the bottom electrode configured by the second conductive film is supported by the first conductive film formed on the outer side of the bottom electrode via the first capacitor insulator film. Accordingly, the occurrence of inclination or collapse of the bottom electrode can be prevented. Thus, the size of the capacitor element can be reduced without incurring reduction in the mechanical strength of the bottom electrode.

It is preferable in the method for manufacturing a semiconductor device of the present invention that the third conductive film be insulated from the first conductive film, and that the first conductive film and the third conductive film be connected to respective power source potentials. In an alternative, the first conductive film and the third conductive film may be maintained at the same potential.

### BRIEF DESCRIPTION OF THE DRAWINGS

FIG. 1 is a sectional view showing the configuration of a semiconductor device according to an embodiment of the invention;

FIGS. 2A to 2G are sectional views consecutively showing manufacturing steps in a method for manufacturing the semiconductor device of FIG. 1;

FIG. 3 is a sectional view showing the configuration of a semiconductor device having a conventional stacked capacitor element;

FIGS. 4A to 4C are sectional views consecutively showing manufacturing steps in a conventional method for manufacturing the semiconductor device of FIG. 5; and

FIG. 5 is a sectional view showing the configuration of a semiconductor device having a conventional Crown-type capacitor element.

### DETAILED DESCRIPTION OF THE PREFERRED EMBODIMENTS

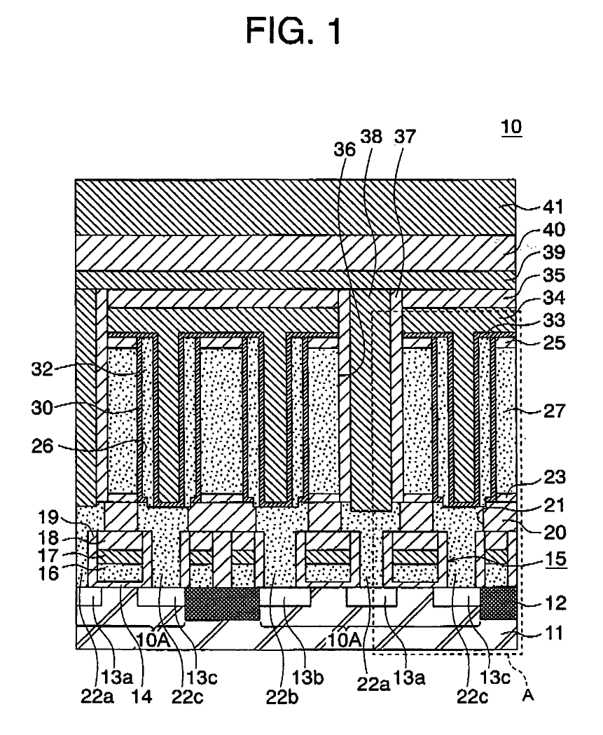

Referring to the accompanying drawings, the present invention will be described hereinafter in further detail based on a preferred embodiment of the present invention. FIG. 1 shows the configuration of a semiconductor device according to the embodiment of the present invention. FIG. 1 shows one of two memory cells formed in one device area, and two memory cells formed in an adjacent device area. An STI (shallow trench isolation) structure 12 is formed in the surface region of the main surface of a silicon substrate, 11 on which the semiconductor device 10 is to be formed. The STI structure 12 divides the substrate area into a plurality of device areas 10A. In the device area 10A, a pair of MIS-type transistors each configuring a part of a memory cell, which also includes a capacitor element, is formed near the main surface of the silicon substrate 11.

A first transistor formed in the device area 10A includes a source 13a and a drain 13b formed in the silicon substrate 11, and a gate electrode 15 formed on the silicon substrate 11 via a gate insulating film 14. A second transistor formed in the device area 10A includes a common source 13a shared with the first transistor, and a drain 13c and a gate electrode 15 formed similarly to the first transistor. The gate electrode 15 includes a polysilicon film 16, and a WSi film 17 formed on the polysilicon film 16, and extends in a row direction to configure a word line for a row of the memory cells. A silicon nitride (SiN) film 18 is formed on the gate electrode 15. A sidewall film 19 made of silicon nitride is formed on the side surface of the gate electrode 15 and on the silicon nitride film 18.

A silicon oxide film 20 is formed on the silicon substrate 11, overlying the transistors. A plurality of contact holes 21 each exposing the source 13a and drains 13b, 13c are formed to penetrate the silicon oxide film 20 and expose a portion of the surface of the sidewall film 19. Contact plugs 22a, 22b, and 22c made of polysilicon are formed to fill the contact hole 21.

A cylindrical bottom electrode 32 made of polysilicon doped with phosphorus is formed in contact with the top end of each of the contact plugs 22b and 22c. A first capacitor insulator film 30 made of aluminum oxide (Al₂O₃) is formed on the outer side surface of the bottom electrode 32. Outside of the first capacitor insulator film 30, there are provided a silicon oxide film 23, a first portion 27 of the top electrode (referred to as first top electrode 27 hereinafter), and a silicon oxide film 25, which are consecutively formed on the silicon oxide film 20. The first top electrode 27 is made of polysilicon doped with phosphorus, and has a thickness of several micrometers. The first top electrode 27 is maintained at the ground potential Vss via a plug and/or an interconnection (not shown).

A second capacitor insulator film 33 made of aluminum oxide is formed on the inner side surface and top surface of the bottom electrode 32, the top surface of the silicon oxide film 25 and the top surface of the contact plugs 22b and 22c exposed through the bottom of the cylindrical bottom electrodes 32. A second portion of the top electrode (referred to as second top electrode hereinafter) 34 of the top electrode is formed in the interior and on the upper surface of the bottom electrode 32 with an intervention of the second capacitor insulator film 33. The second top electrode 34 is made of tungsten. A voltage equal to half the power supply voltage Vcc, which is the maximum voltage applied to a bit line, is applied to the second top electrode 34 via a plug and/or an interconnection (not shown). A silicon oxide film 35 is formed on the second top electrode 34.

A through-hole 36 is formed at the center of the device area 10A, extending from the top surface of the silicon oxide film 35 to the top surface of the contact plug 22a. A sidewall film 37 made of silicon oxide is formed on the side surface of the through-hole 36. A plug 38 made of polysilicon doped with phosphorus is formed to fill the interior of the through-hole 36 via the sidewall film 37.

A bit line 39 made of tungsten is in contact with the top end of the plug 38. Further, an insulating film 40 is formed on the silicon oxide film 35 to cover the bit line 39. A metal interconnect pattern 41 is formed on the insulating film 40. Other insulating films, contact plugs and interconnections etc. necessary to configure the DRAM device are also formed in the semiconductor device 10.

In accordance with the semiconductor device of the present embodiment, the first top electrode 27 is isolated from the second top electrode 34 by the second capacitor insulator film 33 and the silicon oxide film 25. Thus, the first top electrode 27 and the second top electrode 34 may be connected to different power supply sources. In this configuration, particularly by connecting the first top electrode 27 to the ground potential Vss, a larger potential difference can be generated between the bottom electrode 32 and the first top electrode 27, as compared with the conventional Crown-type capacitor element, in which the first and second top electrodes are integrally formed. This can increase the electric charge stored in the capacitor element, to thereby improve the effective storage capacitance of the capacitor element.

In the semiconductor device having the conventional capacitor element, fluctuation of the power source potential (power supply noise) may be generated on the top electrode due to operation of the other capacitor element. This may cause a malfunction in the capacitor element. In the semiconductor device of the present embodiment, the configuration wherein the first top electrode 27 is maintained at the ground potential Vss, and the second top electrode 34 is maintained at the potential of Vcc/2 (i.e., half the power source potential) allows the power supply noise generated on the first top electrode 27 and the power supply noise generated on the second top electrode 34 to cancel each other. Therefore, the power supply noise generated on the top electrode is effectively reduced, and the malfunction of the capacitor element can be prevented accordingly. The first top electrode 27 may be maintained at a potential between the potential of Vcc/2 and the potential of Vss, or maintained at a potential lower than the Vss. Further, the first top electrode 27 may be maintained at Vcc/2, whereas the second top electrode 34 may be maintained at a potential lower than Vcc/2.

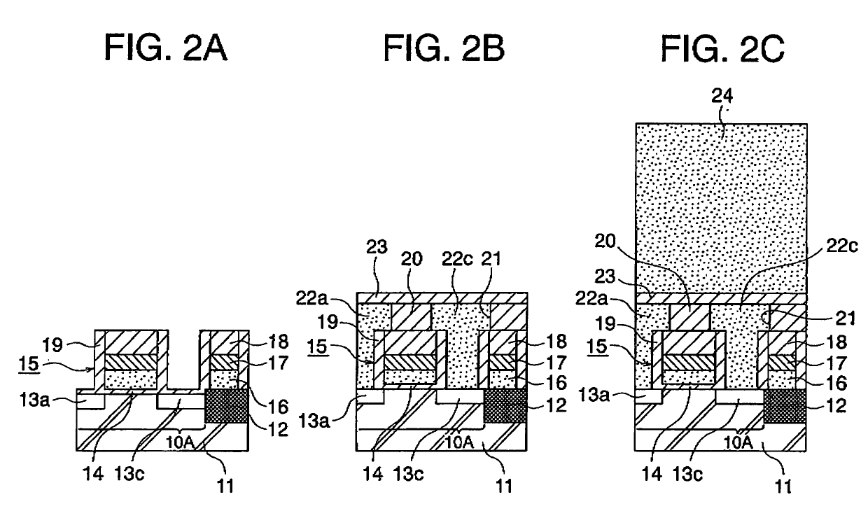

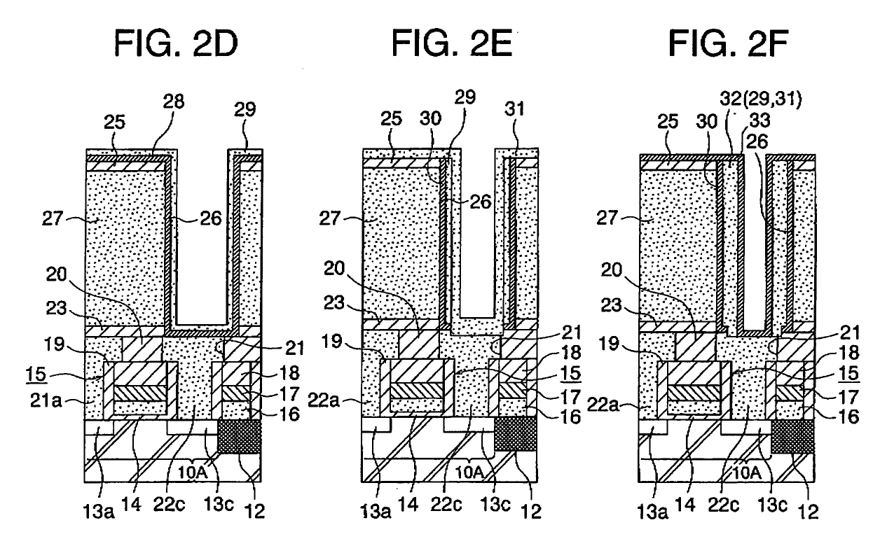

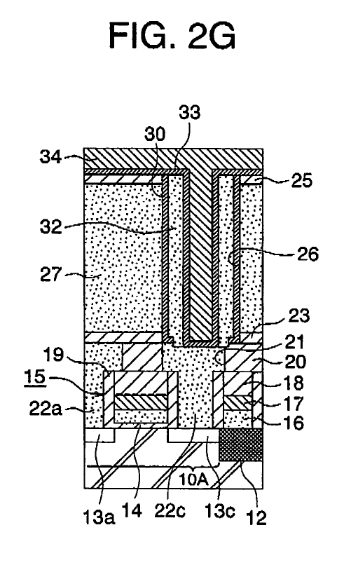

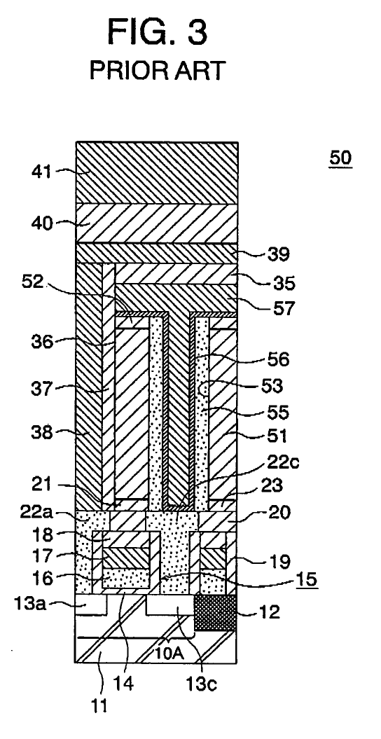

FIGS. 2A to 2G consecutively show the semiconductor device 10 of FIG. 1 in the manufacturing steps thereof in a process according to an embodiment of the present invention. These drawings show the portion of the semiconductor device 10 encircled by a dotted line “A” in FIG. 1. First, the STI structure 12 is formed on a surface portion of the main surface of the silicon substrate 11, whereby the area of the silicon substrate 11 is divided into a plurality of device areas 10A.

Then, the source 13a and drains 13b, 13c are formed in the divided device area 10A, and the gate insulating film 14 is deposited on the silicon substrate 11 to cover the source 13a and drains 13b and 13c.

Then, the polysilicon film 16, WSi film 17 and silicon nitride film 18 are consecutively deposited on the gate insulating film 14.

By using a known photolithographic and etching technique, the silicon nitride film 18 is patterned, followed by patterning the WSi film 17 and polysilicon film 16 by using the patterned silicon nitride film 18 as a mask. Thus, the gate electrode 15 including the polysilicon film 16 and WSi film 17 overlying the polysilicon film 16 is formed. Further, after the silicon nitride film 18 is deposited on the entire surface, the sidewall film 19 made of silicon nitride is formed on both side surfaces of the gate electrode 15 and the silicon nitride film 18 by using deposition and anisotropic etching (FIG. 2A).

Then, the silicon oxide film 20 is deposited on the entire surface. Subsequently, by using a known photolithographic and etching technique, the contact hole 21 for exposing the source 13a and drains 13b, 13c are formed in the silicon oxide film 20 by using a self-alignment process using the sidewall film 19 as a mask. Furthermore, by using a known method, a polysilicon film doped with phosphorus is deposited in the interior of the contact hole 21 to form the contact plugs 22b and 22c. Then, the silicon oxide film 23 is deposited on the entire surface (FIG. 2B).

A polysilicon film doped with phosphorus is deposited to a thickness of several micrometers on the entire surface (FIG. 2C). Subsequently, the silicon oxide film 25 is deposited on the polysilicon film 24, and is patterned. Further, with the patterned silicon oxide film 25 used as a mask, the polysilicon film 24 and the silicon oxide film 23 are etched, thereby forming the opening 26 for exposing the top surface of the contact plug 22a. By the formation of the opening 26, the inner surface of the first top electrode 27 made of polysilicon is obtained, opposing the outer side surface of the bottom electrode. Subsequently, an aluminum oxide film 28 is deposited on the entire surface, and thereafter a polysilicon film 29 doped with phosphorus is deposited to the thickness of several hundreds of angstroms on the entire surface (FIG. 2D).

Subsequently, the polysilicon film 29 and aluminum oxide film 28 formed on the bottom of the opening 26 and on the silicon oxide film 25 are removed by anisotropic etching. In the step of this removal, the aluminum oxide film 28 is protected by the polysilicon film 29 on the side surface of the opening 26. Thus, the first capacitor insulator film 30 configured from the aluminum oxide film 28 is formed on the side surface of the opening 26. Then, a polysilicon film 31 doped with phosphorus is deposited on the entire surface (FIG. 2E).

Then, the polysilicon film 31 on the bottom of the opening 26 and the silicon oxide film 25 is removed by anisotropic etching. Further, the second capacitor insulator film 33 made of aluminum oxide is deposited on the entire surface. The remaining polysilicon film 29 and the polysilicon film 31 are integrated by the heat applied during depositing the second capacitor insulator film 33, configuring the cylindrical bottom electrode 32 (FIG. 2F).

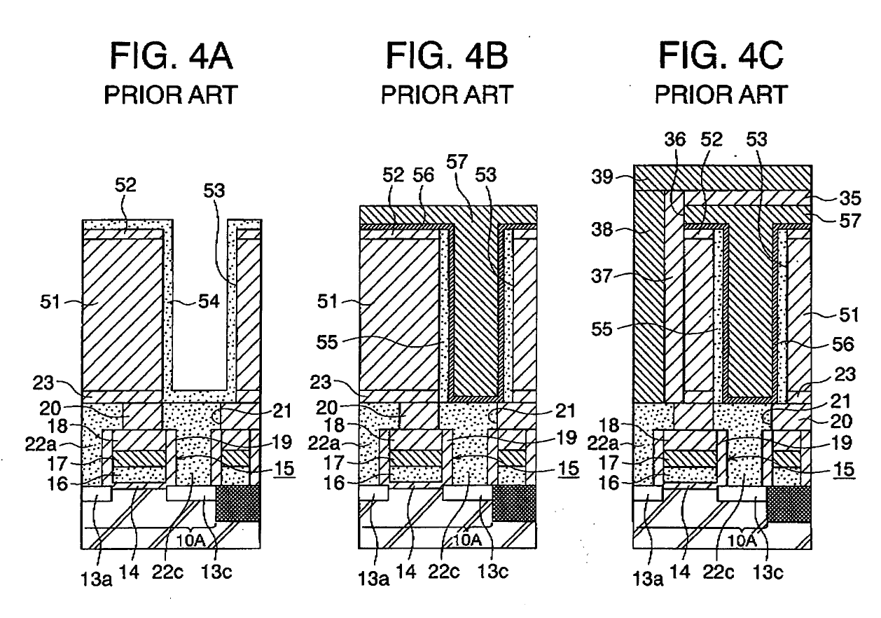

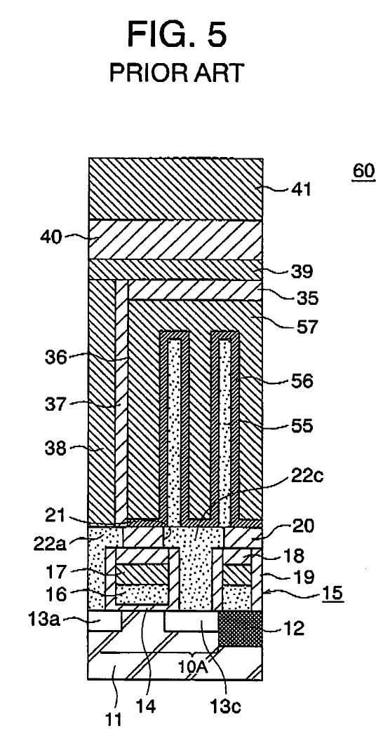

Subsequently, the second top electrode 34 is formed by depositing tungsten on the entire surface including the interior of the opening 26 and (FIG. 4). Further, the silicon oxide film 35 is deposited on the second top electrode 34. Then, by using a known technique, the through-hole 36 for exposing the contact plug 22a in FIG. 1 is formed. After the sidewall film 37 made of silicon oxide is formed on the side surface of the through-hole 36, the plug 38 made of tungsten is formed by filling the interior of the through-hole 36 via the sidewall film 37. Moreover, by using a known technique, the bit line 39, insulating film 40, metal interconnects 41 and the like are formed, to complete the semiconductor device 10 shown in FIG. 1.

According to the method for manufacturing the semiconductor device of the present embodiment, during forming the Crown-type capacitor element, all the side surfaces of the polysilicon film 29 and the polysilicon film 31 configuring the bottom electrode 32 are supported by the first top electrode 27 via the first capacitor insulator film 30. Accordingly, inclination or collapse of the bottom electrode 32 can be prevented. Thus, the capacitor element may be reduced in size while improving the mechanical strength of the bottom electrode and thereby preventing generation of inclination or collapse of the bottom electrode 32 and.

According to the method of manufacturing the semiconductor device of the present embodiment, the polysilicon film 29 is deposited on the aluminum oxide film 28 in the step shown in FIG. 2D. Thus, during the anisotropic etching for removing the aluminum oxide film 28 on the bottom of the opening 26, the aluminum oxide film 28 can be protected by the polysilicon film 29. This allows the thickness of the first capacitor insulator film 30 to be reduced without a malfunction, and thereby increases the capacitance of the capacitor element.

The materials for the constituent elements described in the present embodiment is a mere example. Various materials other than the materials described in the present embodiment may be also used. In addition, a semiconductor device of the CUB structure is exemplified in the present embodiment; however, a semiconductor device of the COB (Capacitor On Bit line) structure may be used in the present invention. Further, aluminum oxide is used for the first capacitor insulator film 30 and second capacitor insulator film 33 in the present embodiment. However, tantalum oxide (Ta₂O₅), silicon nitride, or a combination thereof, etc. can be used instead.

The foregoing description is made based on the preferred embodiment. However, the semiconductor device and the method of manufacturing the same according to the present invention are not limited to the configurations of the above embodiments. A semiconductor device and a method of manufacturing the same in which various corrections and changes are performed from the configurations of the above-mentioned embodiment are also included in the scope of the present invention.

What is claimed is:

1. A semiconductor device comprising:
a semiconductor substrate; and
a cylindrical capacitor overlying said semiconductor substrate and including a bottom electrode, first and second capacitor insulator films and a top electrode, said top electrode including a first electrode portion opposing an outer surface of said bottom electrode with an intervention of said first capacitor insulator film and a second electrode portion insulated from said first electrode portion and opposing an inner surface of said bottom electrode with an intervention of said second capacitor insulator film.

2. The semiconductor device according to claim 1, wherein said second electrode portion is maintained at a potential equal to half a potential of a power source.

3. The semiconductor device according to claim 1, wherein said first electrode portion is maintained at a potential below half the potential of the power source.

4. A method for manufacturing a semiconductor device comprising:
forming a first insulator film overlying a semiconductor substrate;
forming a contact plug penetrating said first insulator film to reach a portion of said semiconductor substrate;
forming a first conductive film on said insulator film and a top surface of said contact plug;
forming a cylindrical opening in said first conductive film to expose said top surface of said contact plug;
forming a first capacitor insulator film on a sidewall of said cylindrical opening;
forming a second conductive film on said first capacitor insulator film and said top surface of said contact plug, to configure a bottom electrode connected to said contact plug;
forming a second capacitor insulator film on said bottom electrode and said contact plug;
forming a third conductive film on said second capacitor insulator film; and
connecting said first and third conductive films to at least one source line having a specific potential, thereby configuring said first and second conductive films as first and second top electrodes.

5. The method according to claim 4, wherein said first and second conductive films are isolated from each other, and said first and second top electrodes are connected respective source lines having different specific potentials.

6. The method according to claim 4, wherein said first and second top electrodes are maintained at a common potential.
